(19) United States
(12) Patent Application Publication
(10) Pub. No.: US 2025/0125785 A1
(43) Pub. Date: Apr. 17, 2025

(54) Vibrating Device And Method For Manufacturing Vibrating Device

(71) Applicant: SEIKO EPSON CORPORATION, Tokyo (JP)

(72) Inventor: Koichi MIZUGAKI, Suwa (JP)

(21) Appl. No.: 18/912,662

(22) Filed: Oct. 11, 2024

(30) Foreign Application Priority Data
Oct. 12, 2023 (JP) 2023-176577

(51) Int. Cl. H03H 9/10; H03H 3/02; H03H 9/19

(52) U.S. Cl. CPC H03H 9/1021; H03H 3/02; H03H 9/19; H03H 2003/022

(57) ABSTRACT

A vibrating device includes a base 10 including a semiconductor substrate 11 having a first surface 11a and a second surface 11b, a circuit element being formed on the first surface 11a, an insulating layer 12 disposed on a first surface 11a side, and a pad electrode 14a disposed between a third surface 10a on a side of the insulating layer 12 opposite from the semiconductor substrate 11 and the first surface 11a and electrically connected to the circuit element, an opening portion 16 that exposes a front surface 14a1 of the pad electrode 14a being formed in the insulating layer 12 at a position overlapping the pad electrode 14a in plan view; a first metal pattern 30A disposed on at least a part of the front surface 14a1; a vibrating element 40 electrically connected to the first metal pattern 30A; and a metal member 18 disposed on the first metal pattern 30A overlapping the front surface 14al in plan view, and electrically connecting the first metal pattern 30A and the vibrating element 40.

The present application is based on, and claims priority from JP Application Serial Number 2023-176577,filed Oct., 12, 2023, the disclosure of which is hereby incorporated by reference herein in its entirety.

### BACKGROUND

### 1. Technical Field

The present disclosure relates to a vibrating device and a method for manufacturing a vibrating device.

### 2. Related Art

JP-A-2021-057755 discloses a method for manufacturing a vibrating device including a base substrate including a semiconductor substrate on which an integrated circuit is formed; a lid to be bonded to the base substrate and including a recess; and a vibrating piece accommodated between the base substrate and the lid. In such a vibrating device, a laminate including a wiring layer or a pad for electrically connecting the integrated circuit and the vibrating piece is disposed on the base substrate. Specifically, a plurality of wires such as a bonding member, a terminal layer, and a wiring layer are provided between the vibrating piece and the pad.

However, in the configuration of the related art, since the plurality of wires are disposed between the vibrating piece and the pad, wiring resistance increases and vibration characteristics are affected, which is a problem.

### SUMMARY

A vibrating device includes: a base including a semiconductor substrate having a first surface and a second surface, a circuit element being formed on the first surface, an insulating layer disposed on a first surface side, and a pad electrode disposed between a surface on a side of the insulating layer opposite from the semiconductor substrate and the first surface and electrically connected to the circuit element, in which an opening portion that exposes a front surface of the pad electrode is formed in the insulating layer at a position overlapping the pad electrode in plan view; a first metal pattern disposed on at least a part of the front surface; a vibrating element electrically connected to the first metal pattern; and a metal member disposed on the first metal pattern overlapping the front surface in plan view and electrically connecting the first metal pattern and the vibrating element.

A method for manufacturing a vibrating device, includes: preparing a base including a semiconductor substrate having a first surface and a second surface, a circuit element being formed on the first surface, an insulating layer disposed on a first surface side, and a pad electrode disposed between a surface on a side of the insulating layer opposite from the semiconductor substrate and the first surface and electrically connected to the circuit element; forming an opening portion in the insulating layer to expose a front surface of the pad electrode, the opening portion overlapping the pad electrode in plan view; forming a first metal layer on the front surface, side surfaces of the opening portion, and one surface of the base; removing, among a first portion including a portion overlapping the pad electrode, a second portion surrounding the first portion in plan view, and a third portion located between the first portion and the second portion in the first metal layer, the third portion; bonding a vibrating element to the first portion via a metal member; and bonding a lid to the second portion.

### BRIEF DESCRIPTION OF THE DRAWINGS

FIG. 1 is a perspective view showing a configuration of a vibrating device.

FIG. 2 is a plan view showing the configuration of the vibrating device.

FIG. 3 is a sectional view of the vibrating device shown in FIG. 2 taken along line III-III.

FIG. 4 is an enlarged sectional view showing a portion IV of the vibrating device shown in FIG. 3.

FIG. 5 is an enlarged plan view showing a portion V of the vibrating device shown in FIG. 2.

FIG. 6 is a sectional view showing a method for manufacturing a vibrating device.

FIG. 7 is a sectional view showing the method for manufacturing a vibrating device.

FIG. 8 is a sectional view showing the method for manufacturing a vibrating device.

FIG. 9 is a sectional view showing the method for manufacturing a vibrating device.

FIG. 10 is a sectional view showing the method for manufacturing a vibrating device.

FIG. 11 is a sectional view showing the method for manufacturing a vibrating device.

FIG. 12 is a sectional view showing the method for manufacturing a vibrating device.

FIG. 13 is a sectional view showing the method for manufacturing a vibrating device.

FIG. 14 is a sectional view showing the method for manufacturing a vibrating device.

FIG. 15 is a sectional view showing a method for manufacturing a vibrating device according to a modification example.

### DESCRIPTION OF EMBODIMENTS

In each of the following drawings, three axes orthogonal to each other will be described as an X-axis, a Y-axis, and a Z-axis. In addition, a direction along the X-axis is referred to as an “X direction”, a direction along the Y-axis is referred to as a “Y direction”, a direction along the Z-axis is referred to as a “Z direction”, an arrow direction is a + direction, and a direction opposite to the + direction is referred to as a − direction. A +Z direction may be referred to as “upper”, “upward”, or “front side”, a −Z direction may be referred to as “lower”, “downward”, or “back side”, and a view from the +Z direction and the −Z direction is also referred to as a plan view or being planar. In addition, a surface on the +side in the Z direction is referred to as an “upper surface” or a “front surface”, and a surface on the − side in the Z direction opposite thereto is referred to as a “lower surface” or a “back surface”.

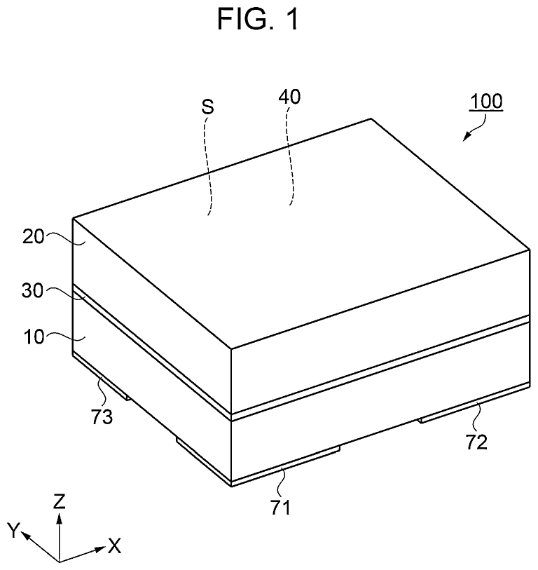

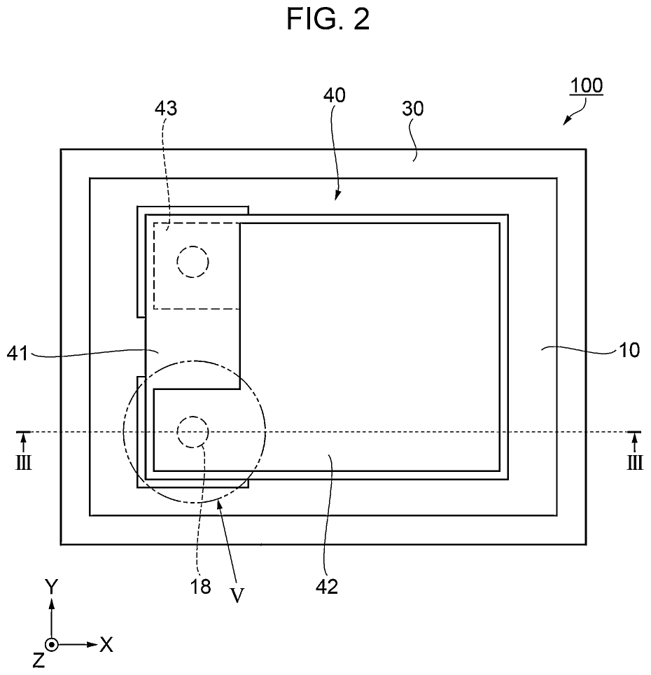

First, a configuration of a vibrating device 100 will be described with reference to FIGS. 1 to 5. The vibrating device 100 shown in FIG. 2 is shown with a lid 20 removed for the sake of convenience in describing the internal configuration.

As shown in FIGS. 1 to 3, the vibrating device 100 includes a base 10; the lid 20 disposed on the base 10; a bonding layer 30 that bonds the base 10 and the lid 20 to each other; and a vibrating element 40 mounted on the base 10.

As shown in FIG. 2, the bonding layer 30 surrounds the vibrating element 40, in other words, is formed in a frame shape in a region where the base 10 and the lid 20 are bonded to each other. The bonding layer 30 is bonded by, for example, surface activated bonding using gold (Au). The bonding is not limited to using gold (Au), and copper (Cu), aluminum (Al), or the like may be used.

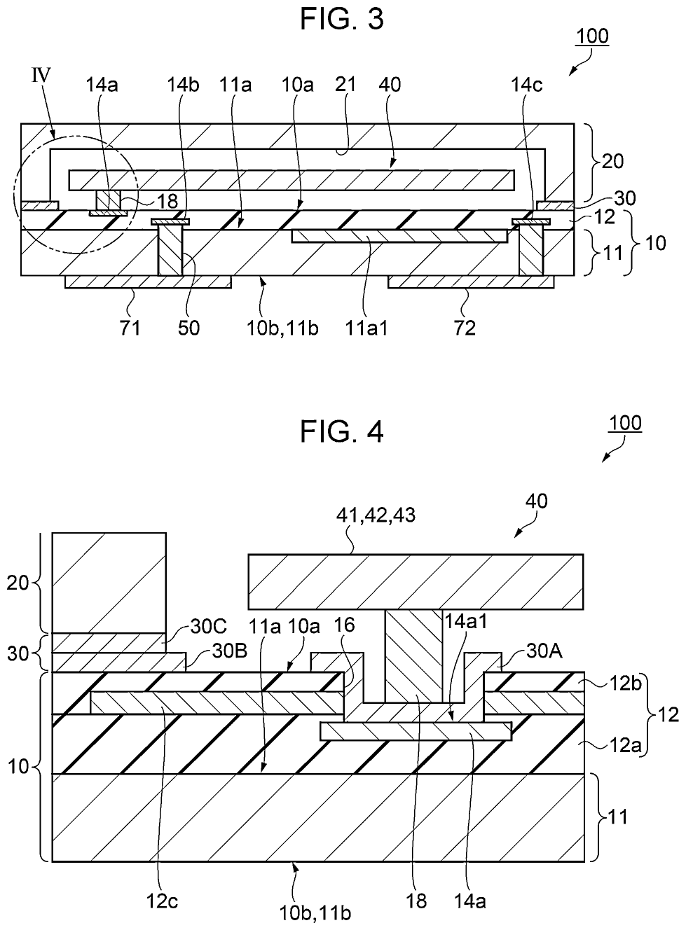

As shown in FIG. 3, the vibrating device 100 includes an oscillation circuit, and includes the base 10, the lid 20, and the bonding layer 30 that bonds the base 10 and the lid 20 to each other. The base 10 includes a semiconductor substrate 11 and an insulating layer 12.

The semiconductor substrate 11 has a first surface 11a and a second surface 11b that is a surface facing the first surface 11a. The semiconductor substrate 11 is, for example, a silicon substrate. A circuit element 11a1 including transistors and the like is formed on the first surface 11a of the semiconductor substrate 11.

The circuit element 11a1 is, for example, a circuit in which active elements such as a plurality of transistors (not shown) are electrically connected to each other by wires. For example, the circuit element 11a1 oscillates the vibrating element 40. A temperature compensation circuit or the like that corrects the vibration characteristics of the vibrating element 40 according to a change in temperature may be used.

The insulating layer 12 made of an oxide is disposed on the first surface 11a of the semiconductor substrate 11 to cover the circuit element 11a1. A third surface 10a on a side of the insulating layer 12 opposite from the semiconductor substrate 11 is flattened by polishing.

The material of the insulating layer 12 is, for example, SiO₂ (silicon oxide). The material is not limited to SiO₂ (silicon oxide), and may be a material such as SiN (silicon nitride).

A plurality of wiring layers (not shown) are provided in the insulating layer 12. Specifically, pad electrodes 14a, 14b, and 14c, wiring layers, or the like electrically connected to the circuit element 11a1 are disposed between the third surface 10a on the side of the insulating layer 12 opposite from the semiconductor substrate 11 and the first surface 11a, namely, in the insulating layer 12.

As shown in FIG. 4, the pad electrode 14a is electrically connected to the vibrating element 40 via a first metal pattern 30A and a metal member 18 that functions as a bump. The pad electrode 14a is made of, for example, aluminum (Al).

Specifically, the insulating layer 12 includes a first insulating layer 12a, a passivation film 12c, and a second insulating layer 12b. An opening portion 16 extending through the second insulating layer 12b and the passivation film 12c and extending partway into the first insulating layer 12a is provided on the pad electrode 14a, namely, at a position overlapping the pad electrode 14a in plan view.

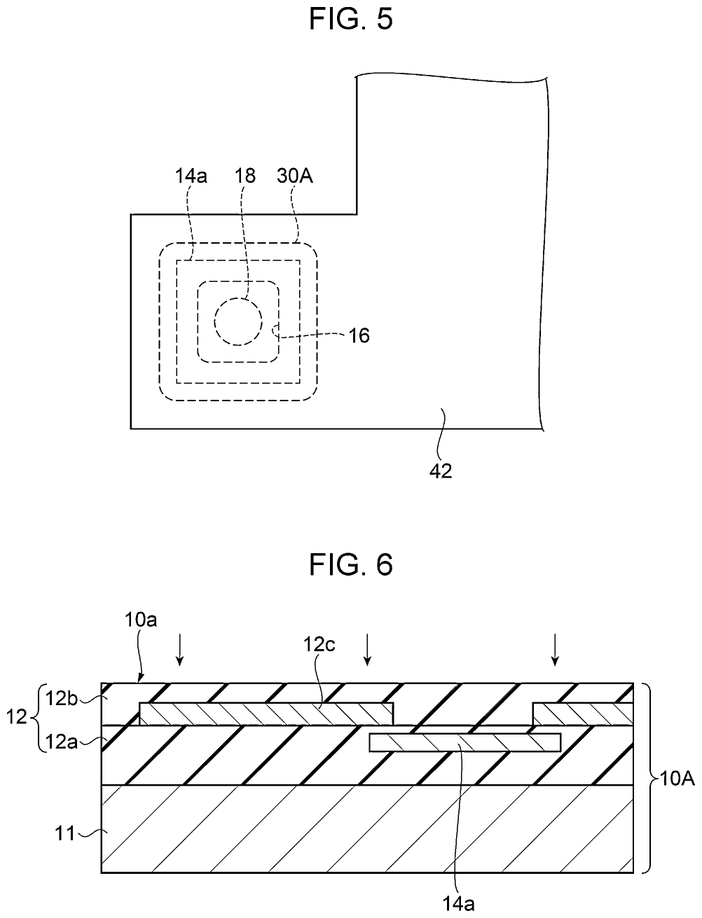

A part of a front surface 14a1 of the pad electrode 14a is exposed by providing the opening portion 16. As shown in FIGS. 4 and 5, the first metal pattern 30A is disposed across the front surface 14a1 of the pad electrode 14a which is exposed, side surfaces of the opening portion 16, and the third surface 10a around the opening portion 16.

The first metal pattern 30A is, for example, a laminated film of titanium (Ti) and gold (Au). Titanium-tungsten (TiW) may be used instead of Ti. The metal member 18 is disposed on the first metal pattern 30A overlapping the front surface 14a1 in plan view.

The pad electrodes 14a, 14b, and 14c and the circuit element 11a1 are electrically connected via through electrodes 50 to any of external connection terminals 71, 72, and 73 disposed on a second surface 10b of the base 10.

Specifically, the external connection terminals 71, 72, and 73 include an external power supply terminal, an external ground terminal, and an external oscillation output terminal. With such a configuration, the circuit element 11a1 is driven by power supply supplied from the outside via the external power supply terminal, oscillates the vibrating element 40 to generate an oscillation signal, and outputs the oscillation signal to the outside via the external oscillation output terminal.

As shown in FIG. 2, the vibrating element 40 includes an element substrate 41; a first excitation electrode 42 disposed on one surface of the element substrate 41; and a second excitation electrode 43 disposed on the other surface of the element substrate 41.

As the constituent material of the first excitation electrode 42 or the second excitation electrode 43, for example, a metal material such as gold (Au), silver (Ag), platinum (Pt), palladium (Pd), iridium (Ir), copper (Cu), aluminum (Al), nickel (Ni), chromium (Cr), titanium (Ti), or tungsten (W), or an alloy containing these metal materials can be used.

The vibrating element 40 is fixed onto the first metal pattern 30A by being bonded by the metal member 18. The metal member 18 may be a microbump, a stud bump, or the like. The metal member 18 is made of, for example, gold (Au).

As shown in FIG. 3, the lid 20 is formed of, for example, a silicon substrate, and is a box-shaped container including a recess 21 for forming a cavity S as an accommodation space. The vibrating element 40 is accommodated in the recess 21 of the lid 20 by bonding the base 10 and the lid 20 to each other via the bonding layer 30. Namely, the vibrating element 40 is hermetically sealed in a space surrounded by the base 10 and the lid 20. The hermetically sealed space is referred to as the cavity S.

Next, a method for manufacturing the vibrating device 100 will be described with reference to FIGS. 6 to 14.

First, in a step shown in FIG. 6, a base 10A is prepared. Specifically, first, the circuit element 11a1 that includes transistors and the like and is shown in FIG. 3 is formed in the semiconductor substrate 11. Next, the insulating layer 12 including insulating layers or wiring layers, the pad electrodes 14a, 14b, and 14c, and the passivation film 12c is formed on the semiconductor substrate 11. The insulating layer 12, namely, the insulating layers 12a and 12b are formed using, for example, a chemical vapor deposition (CVD) method. A thickness of the insulating layer 12 is, for example, 4 μm. The insulating layer 12 may be formed using a sputtering method.

Thereafter, the third surface 10a of the insulating layer 12 is flattened. Specifically, the third surface 10a on the side of the insulating layer 12 opposite from the semiconductor substrate 11 is subjected to a flattening process by using, for example, a chemical mechanical polishing (CMP) method. Accordingly, the third surface 10a of the insulating layer 12, which is uneven, becomes flat. The thickness of the insulating layer 12 after flattening is, for example, 1 μm.

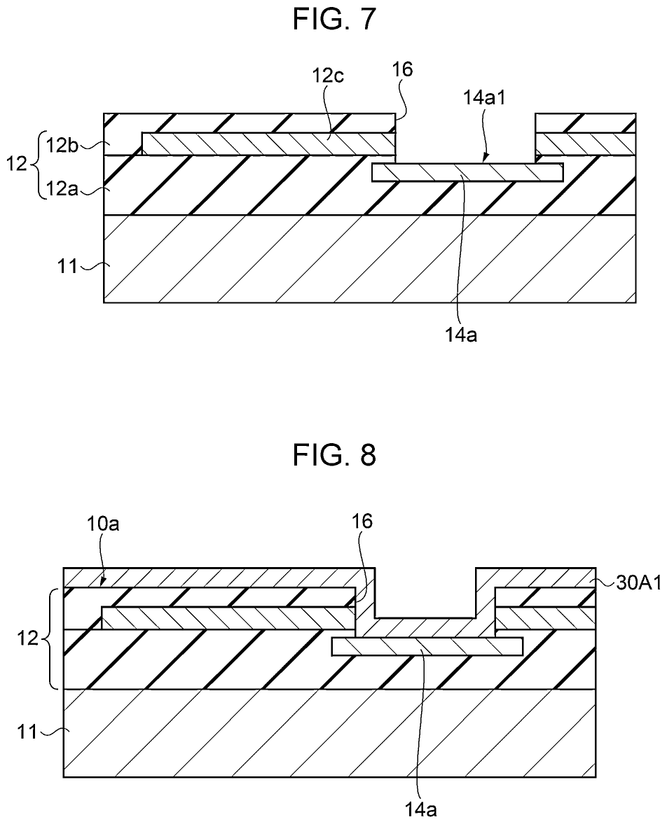

Next, in a step shown in FIG. 7, the opening portion 16 is formed. Specifically, the opening portion 16 is formed in a region of the insulating layer 12 by using, for example, a photolithography technique and an etching technique, the region overlapping the pad electrode 14a in plan view. Accordingly, a part of the front surface 14a1 of the pad electrode 14a is exposed.

Next, in a step shown in FIG. 8, a first metal layer 30A1 is formed on the entire front surface of the insulating layer 12 by, for example, a sputtering method. A foundation layer of the first metal layer 30A1 is made of, for example, titanium (Ti). A thickness of the foundation layer is, for example, 0.05 μm. An outermost layer of the first metal layer 30A1 is made of, for example, gold (Au). A thickness of the outermost layer is, for example, 0.15 μm or less. Since the first metal layer 30A1 is a laminated film of titanium (Ti) and gold (Au), an Au film can be formed while relieving stress of the film.

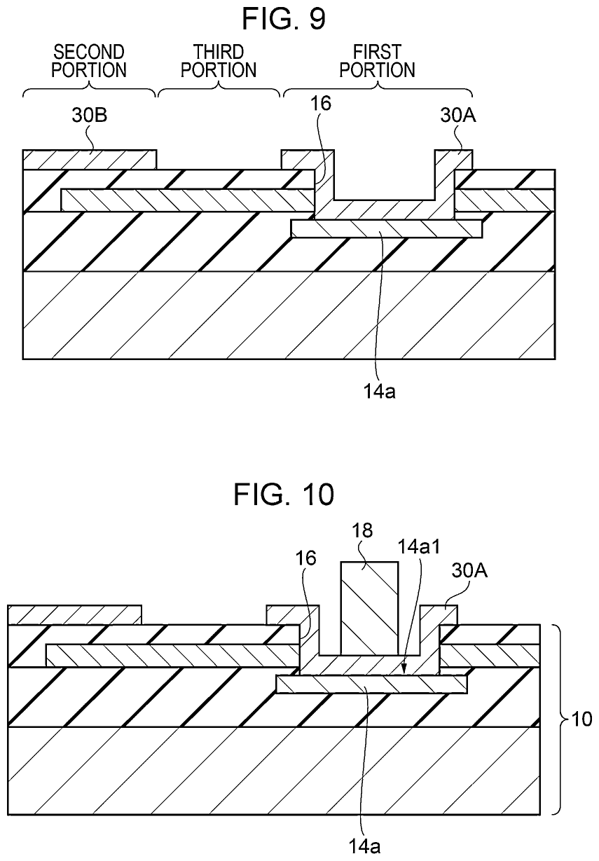

Next, in a step shown in FIG. 9, the first metal pattern 30A and a second metal pattern 30B are formed. Specifically, the first metal pattern 30A and the second metal pattern 30B are formed in the first metal layer 30A1 by using a photolithography technique and an etching technique. The second metal pattern 30B is also referred to as a bonding layer 30B.

Since the thickness of Au of the outermost layer is 0.15 μm that is a thin film thickness, the flatness is good, and resistance of the first metal pattern 30A on the pad electrode 14a can be reduced. In addition, since the same laminated film as the first metal pattern 30A is used for the second metal pattern 30B, the bonding of the base 10 and the lid 20 can be performed with high reliability. A surface roughness Ra of the first metal pattern 30A and the second metal pattern 30B is 2 nm or less.

As shown in FIG. 9, in the first metal layer 30A1, a portion partially overlapping the pad electrode 14a is referred to as a first portion, a portion surrounding the first portion in plan view is referred to as a second portion, and a portion located between the first portion and the second portion is referred to as a third portion. Namely, the third portion of the first metal layer 30A1 is removed. As described above, the first metal pattern 30A to be bonded to the metal member 18 later and the second metal pattern 30B that becomes a part of the bonding layer 30 are formed.

Next, in a step shown in FIG. 10, the metal member 18 that is a bump is formed. Specifically, the metal member 18 is formed on a portion of the first metal pattern 30A, the portion overlapping the front surface 14a1 of the pad electrode 14a in plan view. The metal member 18 is made of Au (gold) as described above, and is formed by an electroless plating method.

A height of the metal member 18 is, for example, 15 μm. A diameter of the metal member 18 is, for example, 30 μm. Since the outermost layer of the first metal layer 30A1 and the metal member 18 are made of the same gold (Au), the bonding of the first metal pattern 30A and the metal member 18 can be performed easily and reliably. In addition, wiring resistance, namely, electric resistance of a bonding surface between the first metal pattern 30A and the metal member 18 can be suppressed, and the deterioration of the vibration characteristics of the vibrating element 40 can be suppressed.

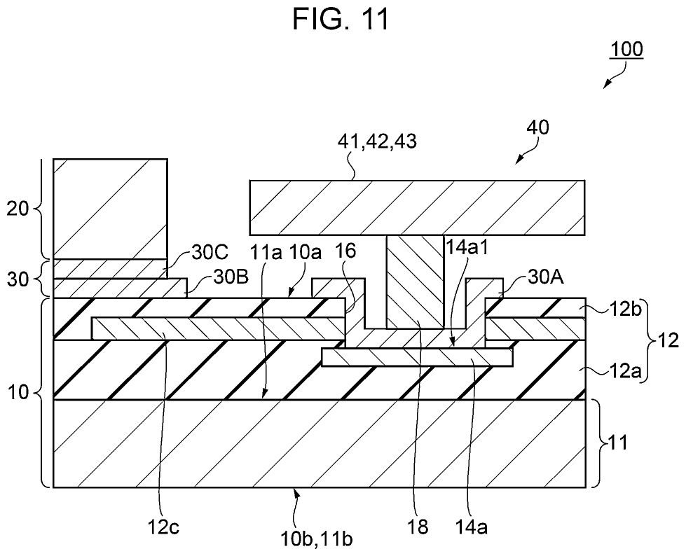

Next, in a step shown in FIG. 11, the vibrating element 40 is bonded to the metal member 18. Specifically, the first excitation electrode 42 shown in FIG. 2 is formed on one side of the element substrate 41 made of a piezoelectric material such as quartz, and the second excitation electrode 43 shown in FIG. 2 is formed on the other side of the element substrate 41. Thereafter, the completed vibrating element 40 and the metal member 18 are bonded to each other.

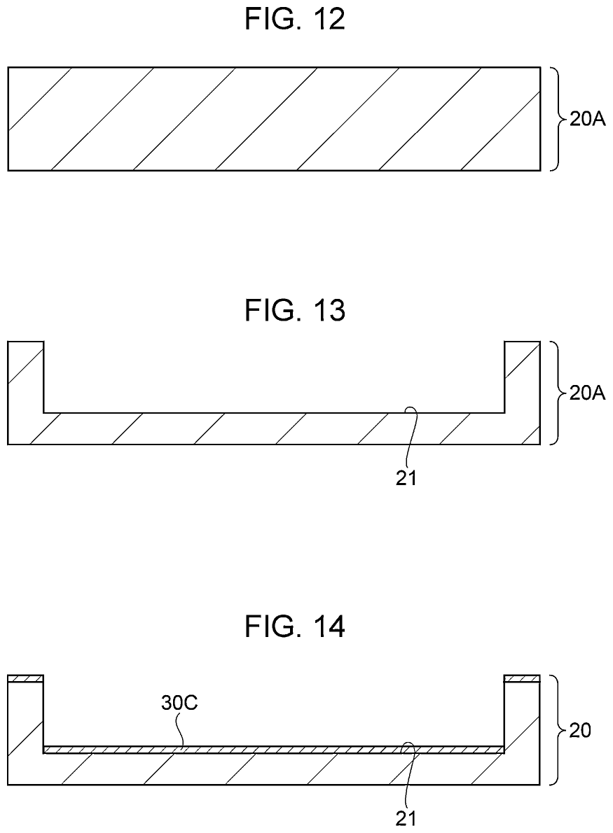

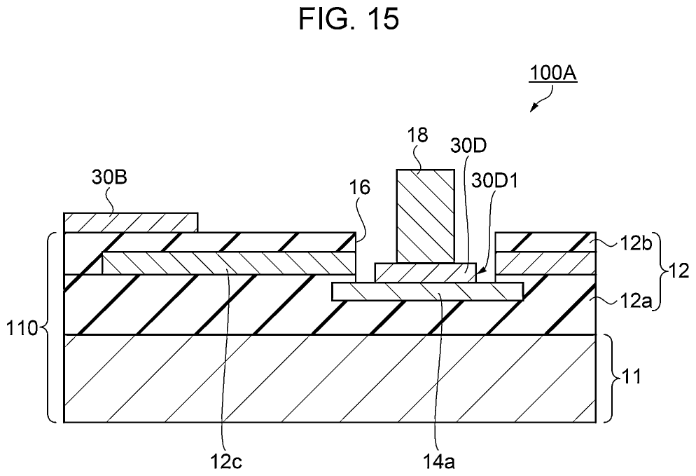

Next, in steps shown in FIGS. 12 to 14, the lid 20 is formed. First, in the step shown in FIG. 12, a silicon substrate 20A is prepared. Next, as shown in FIG. 13, the recess 21 is formed in the silicon substrate 20A. Thereafter, in the step shown in FIG. 14, a bonding layer 30C of Ti/Au is laminated on an entire front surface on a side of the silicon substrate 20A by using, for example, a sputtering method, the recess 21 being provided on the side.

A thickness of Ti is, for example, 0.04 μm. A thickness of Au is, for example, 0.02 μm. The bonding layer 30C is not limited to being made of Ti/Au, and may be made of TiW/Au or the like. As described above, the lid 20 is completed.

Next, in a state where the vibrating element 40 is accommodated in the accommodation space between the base 10 and the lid 20, the front surfaces of the bonding layers 30B and 30C, namely Au, are bonded by, for example, activation bonding or the like using argon gas in a vacuum atmosphere at normal temperature. As described above, as shown in FIG. 3, the vibrating element 40 is hermetically sealed by the bonding layer 30, the base 10, and the lid 20.

Next, the through electrodes 50 are formed in the base 10. Specifically, first, in the base 10, through-holes are formed in regions overlapping the pad electrodes 14b and 14c in plan view by using a photolithography technique and an etching technique. Thereafter, for example, by embedding tungsten (W) in the through-holes and patterning metal films on the second surface 10b of the base 10, the external connection terminals 71, 72, and 73 are completed. As described above, the vibrating device 100 is completed.

As described above, the vibrating device 100 according to the present embodiment includes: the base 10 including the semiconductor substrate 11 having the first surface 11a and the second surface 11b, the circuit element 11a1 being formed on the first surface 11a, the insulating layer 12 disposed on a first surface 11a side, and the pad electrode 14a disposed between the third surface 10a on the side of the insulating layer 12 opposite from the semiconductor substrate 11 and the first surface 11a and electrically connected to the circuit element 11a1, in which the opening portion 16 that exposes the front surface 14a1 of the pad electrode 14a is formed in the insulating layer 12 at a position overlapping the pad electrode 14a in plan view; the first metal pattern 30A disposed on at least a part of the front surface 14a1; the vibrating element 40 electrically connected to the first metal pattern 30A; and the metal member 18 disposed on the first metal pattern 30A overlapping the front surface 14a1 in plan view and electrically connecting the first metal pattern 30A and the vibrating element 40.

According to this configuration, since the pad electrode 14a and the vibrating element 40 are electrically connected to each other via the metal member 18 on the first metal pattern 30A, compared to when the pad electrode 14a and the vibrating element 40 are electrically connected to each other via a plurality of metal wires, an increase in electric resistance between the pad electrode 14a and the vibrating element 40 can be suppressed. Therefore, the deterioration of the vibration characteristics of the vibrating element 40 can be suppressed.

In addition, since the second metal pattern 30B is formed to be thin, flatness can be ensured, and the base 10 and the lid 20 can be favorably bonded to each other. In addition, since an outermost layer of the second metal pattern 30B and an outermost layer of the first metal pattern 30A are made of the same material, Au, the number of manufacturing steps can be reduced, and the cost can be suppressed. In addition, by setting the film thickness of Au of the outermost layer of the second metal pattern 30B to 150 nm or less, the surface roughness Ra of Au can be made to 2 nm or less.

In addition, when the outermost layer of the first metal pattern 30A is formed to be thin, the resistance increases; however, since the metal member 18 made of Au is disposed on the first metal pattern 30A, an increase in resistance can be suppressed. Therefore, for example, the deterioration of the vibration characteristics can be suppressed. Further, by making the metal member 18 the same material, Au, as the outermost layer of the first metal pattern 30A, the metal member 18 can be easily grown by a plating method.

In addition, in the vibrating device 100 according to the present embodiment, it is preferable that the outermost layer of the first metal pattern 30A and the metal member 18 are made of the same material. According to this configuration, since the first metal pattern 30A and the metal member 18 are made of the same material, the bonding of the first metal pattern 30A and the metal member 18 can be performed more easily and reliably.

In addition, in the vibrating device 100 according to the present embodiment, it is preferable that the outermost layer of the first metal pattern 30A is made of gold (Au). According to this configuration, since Au is used for the outermost layer, electric resistance of the bonding surface between the first metal pattern 30A and the metal member 18 can be suppressed, and the deterioration of the vibration characteristics of the vibrating element 40 can be suppressed.

In addition, in the vibrating device 100 according to the present embodiment, it is preferable that the foundation layer of the first metal pattern 30A is made of titanium (Ti). According to this configuration, since Ti is used for the foundation layer, Au can be laminated on the foundation layer in a favorable state.

In addition, it is preferable that the vibrating device 100 according to the present embodiment further includes the lid 20 that accommodates the vibrating element 40, and it is preferable that the second metal pattern 30B for bonding the lid 20 is disposed on the base 10. According to this configuration, since the second metal pattern 30B is disposed, the vibrating element 40 can be sealed in the cavity S by bonding the base 10 and the lid 20 to each other using the second metal pattern 30B.

In addition, in the vibrating device 100 according to the present embodiment, it is preferable that the semiconductor substrate 11 includes an oscillation circuit and the pad electrode 14a is electrically connected to the oscillation circuit. According to this configuration, the vibrating device 100 can be made to function as an oscillator, and the oscillator can be used with high performance.

In addition, the method for manufacturing the vibrating device 100 according the present embodiment, includes: preparing the base 10 including the semiconductor substrate 11 having the first surface 11a and the second surface 11b, the circuit element 11a1 being formed on the first surface 11a, the insulating layer 12 disposed on the first surface 11a side, and the pad electrode 14a disposed between the third surface 10a on the side of the insulating layer 12 opposite from the semiconductor substrate 11 and the first surface 11a and electrically connected to the circuit element 11a1; forming the opening portion 16 in the insulating layer 12 to expose the front surface 14a1 of the pad electrode 14a, the opening portion 16 overlapping the pad electrode 14a in plan view; forming the first metal layer 30A1 on the front surface 14a1, the side surfaces of the opening portion 16, and the third surface of the base 10; removing, among the first portion overlapping a part of the pad electrode 14a, the second portion surrounding the first portion in plan view, and the third portion located between the first portion and the second portion in the first metal layer 30A1, the third portion; bonding the vibrating element 40 to the first portion via the metal member 18; and bonding the lid 20 to the second portion.

According to this method, since the pad electrode 14a and the vibrating element 40 are electrically connected to each other via the metal member 18 at the first portion of the first metal pattern 30A, compared to when the pad electrode 14a and the vibrating element 40 are electrically connected to each other via a plurality of metal wires, an increase in electric resistance between the pad electrode 14a and the vibrating element 40 can be suppressed. Therefore, the deterioration of the vibration characteristics of the vibrating element 40 can be suppressed. In addition, since the opening portion 16 of the pad electrode 14a is covered with the first metal pattern 30A, corrosion of the front surface 14a1 of the pad electrode 14a can be suppressed.

In addition, in the method for manufacturing the vibrating device 100 according to the present embodiment, it is preferable that the outermost layer of the first metal layer 30A1 and the metal member 18 are made of the same material. According to this method, since the outermost layer of the first metal layer 30A1 and the metal member 18 are made of the same material, the bonding of the first metal layer 30A1 and the metal member 18 can be performed easily and reliably.

In addition, in the method for manufacturing the vibrating device 100 according to the present embodiment, it is preferable that the outermost layer of the first metal layer 30A1 is made of gold (Au). According to this method, since Au is used for the outermost layer, electric resistance of the bonding surface between the first metal pattern 30A and the metal member 18 can be suppressed, and the deterioration of the vibration characteristics of the vibrating element 40 can be suppressed.

In addition, in the method for manufacturing the vibrating device 100 according to the present embodiment, it is preferable that the first metal layer 30A1 includes the foundation layer made of titanium (Ti) and the outermost layer made of gold (Au). According to this method, since the above-mentioned materials are laminated, Au can be laminated on the foundation layer in a favorable state.

In addition, in the method for manufacturing the vibrating device 100 according to the present embodiment, it is preferable that the first metal layer 30A1 includes the foundation layer made of titanium-tungsten (TiW) and the outermost layer made of gold (Au). According to this method, since the above-mentioned materials are laminated, Au can be laminated on the foundation layer in a favorable state.

Hereinafter, a modification example of the above-described embodiment will be described.

As described above, the outer shape of the first metal pattern 30A is not limited to being provided from the front surface 14a1 of the pad electrode 14a to a periphery of the opening portion 16, and may be as shown in FIG. 15. As shown in FIG. 15, in a base 110 of the modification example, an outer shape 30D1 of a first metal pattern 30D is disposed inside the side surfaces of the opening portion 16.

In such a manner, since the outer shape 30D1 of the first metal pattern 30D is disposed inside the side surfaces of the opening portion 16, compared to when the outer shape of the first metal pattern 30A is located outside the opening portion 16 as in the above-described embodiment, a parasitic capacitance generated between the first metal pattern 30D and the opening portion 16 can be suppressed, and an influence on the electrical characteristics of a vibrating device 100A can be suppressed.

As described above, in the vibrating device 100A of the modification example, it is preferable that the outer shape 30D1 of the first metal pattern 30D is disposed inside the side surfaces of the opening portion 16. According to this configuration, since the outer shape 30D1 of the first metal pattern 30D is disposed inside the side surfaces of the opening portion 16, compared to when the outer shape 30D1 of the first metal pattern 30D is disposed outside the opening portion 16, the parasitic capacitance generated between the first metal pattern 30D and the opening portion 16 can be suppressed, and an influence on the electrical characteristics of the vibrating element 40 can be suppressed.

What is claimed is:

1. A vibrating device comprising:
a base including
a semiconductor substrate having a first surface and a second surface, a circuit element being formed on the first surface,
an insulating layer disposed on a first surface side, and
a pad electrode disposed between a surface of the insulating layer on a side opposite from the semiconductor substrate and the first surface and electrically connected to the circuit element,
an opening portion that exposes a front surface of the pad electrode being formed in the insulating layer at a position overlapping the pad electrode in plan view;
a first metal pattern disposed on at least a part of the front surface;
a vibrating element electrically connected to the first metal pattern; and
a metal member disposed on the first metal pattern overlapping the front surface in plan view and electrically connecting the first metal pattern and the vibrating element.

2. The vibrating device according to claim 1,
wherein an outer shape of the first metal pattern is disposed inside side surfaces of the opening portion.

3. The vibrating device according to claim 1,
wherein an outermost layer of the first metal pattern and the metal member are made of a same material.

4. The vibrating device according to claim 1,
wherein an outermost layer of the first metal pattern is made of gold (Au).

5. The vibrating device according to claim 4,
wherein a foundation layer of the first metal pattern is made of titanium (Ti).

6. The vibrating device according to claim 1, further comprising:
a lid that accommodates the vibrating element,
wherein a second metal pattern for bonding the lid is disposed on the base.

7. The vibrating device according to claim 1,
wherein the semiconductor substrate includes an oscillation circuit, and
the pad electrode is electrically connected to the oscillation circuit.

8. A method for manufacturing a vibrating device, comprising:
preparing a base including
a semiconductor substrate having a first surface and a second surface, a circuit element being formed on the first surface,
an insulating layer disposed on a first surface side, and
a pad electrode disposed between a surface of the insulating layer on a side opposite from the semiconductor substrate and the first surface and electrically connected to the circuit element;
forming an opening portion in the insulating layer to expose a front surface of the pad electrode, the opening portion overlapping the pad electrode in plan view;
forming a first metal layer on the front surface, side surfaces of the opening portion, and one surface of the base;
removing, among a first portion including a portion overlapping the pad electrode, a second portion surrounding the first portion in plan view, and a third portion located between the first portion and the second portion in the first metal layer, the third portion;
bonding a vibrating element to the first portion via a metal member; and
bonding a lid to the second portion.

9. The method for manufacturing a vibrating device according to claim 8,
wherein an outermost layer of the first metal layer and the metal member are made of a same material.

10. The method for manufacturing a vibrating device according to claim 8,
wherein an outermost layer of the first metal layer is made of gold (Au).

11. The method for manufacturing a vibrating device according to claim 8,
wherein the first metal layer includes a foundation layer made of titanium (Ti) and an outermost layer made of gold (Au).

12. The method for manufacturing a vibrating device according to claim 8,
wherein the first metal layer includes a foundation layer made of titanium-tungsten (TiW) and an outermost layer made of gold (Au).
